(19) United States
(12) Patent Application Publication
(10) Pub. No.: US 2026/0066244 A1
(43) Pub. Date: Mar. 5, 2026

(54) Chamber with Grounded Ion Filter for Enhanced Atomic Layer Etching Processes

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/826,106

(22) Filed: Sep. 5, 2024

(51) Int. Cl. H01J 37/32

(52) U.S. Cl. CPC H01J 37/32899; H01J 37/32091; H01J 37/32422; H01J 37/3244; H01J 2237/2007; H01J 2237/332; H01J 2237/334

(57) ABSTRACT

A plasma process chamber is designed with an upper section functioning as an inductively coupled plasma (ICP) chamber for generating neutrals, and a lower section operating as a capacitively coupled plasma (CCP) chamber for generating high-energy ions. These sections are separated by a grounded ion filter (GIF), composed of conductive materials such as aluminum or silicon. The GIF blocks ions while allowing neutrals to pass, preventing ions from reaching the substrate during the surface modification step of the atomic layer etching (ALE) process. This design provides enhanced control over the ALE process, resulting in more precise substrate modification and improved etching efficiency.

### BACKGROUND OF THE INVENTION

### 1. Field of Invention

The present invention generally relates to the field of plasma processing. More specifically, it relates to a novel process chamber design for atomic layer etching (ALE) to improve ideality of the ALE process and to achieve better results on a substrate.

### 2. Description of the Prior Art

Reactive ion etching (RIE) is a predominant technology in semiconductor manufacturing. In RIE, diverse species including neutrals, radicals, and ions concurrently influence the etching process. A key characteristic of RIE is the synergistic interaction between ion and neutral fluxes, which significantly enhances the etching rate. This synergistic effect was first described by Coburn and Winters in “Ion- and electron-assisted gas-surface chemistry—an important effect in plasma etching,” published in J. Appl. Phys., vol. 50, pages 3189-3196 (1979). They reported increased silicon etching rates when using an argon ion beam, a XeF2 neutral beam, and their combination. Further, Gottscho et al., in “Microscopic uniformity in plasma etching” (J. Vac. Sci. Technol., B10, pages 2133-2147, 1992), developed a model to quantify this synergy for the etching rate ER:

$$ER = \frac{υ {E}_{i} {J}_{i}}{1 + ( υ {E}_{i} {J}_{i} ) / ( {υ}_{n} {sJ}_{n )}} , \qquad [ 1 ]$$

where υ represents the volume removed per unit bombardment energy for a saturated surface (cm³/eV), Eᵢ the ion energy (eV), Jᵢ the ion flux to the surface (cm²/s), υₙ the volume removed per reacting neutral (cm³), Jₙ the neutral flux to the surface and s the sticking probability of the neutral species on the bare surface.

Achieving effective RIE necessitates the presence of both ion and neutral fluxes to exploit the synergy identified by Coburn and Winters. However, it is increasingly complex in modern etching apparatus to balance these fluxes, particularly for etching high aspect ratio structures with dimensions shrinking to nanometer scale. Uniform results across 300 mm wafers and consistent repeatability in production pose additional challenges.

Over the past several decades, advancements in etching apparatus features have been made to enhance uniformity. For instance, the evolution of plasma sources from a single coil (U.S. Pat. No. 4,948,458 to Ogle) to multiple coils (U.S. Pat. No. 6,164,241 to Chen et al.) has been notable, either in the form of inductively coupled plasma (ICP) or transformer coupled plasma (TCP). Additionally, gas injection techniques have been improved, incorporating multiple injection points to ensure a uniform plasma within the vacuum reactor, as described in U.S. Pat. No. 8,231,799 to Bera et al. and U.S. Pat. No. 10,825,659 to Treadwell. Further enhancements include optimizing the electrostatic chuck (ESC) to feature multiple zones with independently adjustable temperatures (U.S. Pat. No. 9,713,200 to Pease and U.S. Pat. No. 10,056,225 to Gaff et al.).

A radio frequency (RF) power generator, coupled to the ESC, provides a bias for the ions in the plasma in addition to the plasma sheath. This coupling, facilitated through a blocking capacitor, helps establish a stable plasma sheath by preventing electron flow to the ground, as detailed in U.S. Pat. No. 5,302,240 to Hori et al. Moreover, various pulsing schemes for RF power generators have been implemented to improve ion energy and angular momentum distribution, thereby maximizing the synergetic effects between ions and neutrals, as described in U.S. Pat. No. 8,264,154 to Banner et al. and U.S. Pat. No. 10,121,639 to Kanarik. RF power generators with tailored waveforms, as discussed by Wang et al. in “Experimental demonstration of multifrequency impedance matching for tailored voltage waveform plasmas” (J. Vac. Sci. Technol. A37, 021303, pages 1-11, 2019), have also been employed to precisely control ion energy.

Additionally, gases can be pulsed in a cyclic process to enhance performance, as disclosed in U.S. Pat. No. 10,121,639 to Kanarik. This cyclic approach segments the RIE process into steps, each optimized with a different set of process gases.

Despite these improvements, achieving the required uniformity across a 300 mm wafer for critical dimension (CD), loading, and profile remains a significant challenge, often entailing considerable expense.

Plasma enhanced ALE (simply as ALE throughout this disclosure) has been developed to address the limitations of RIE. ALE apparatus has evolved from the RIE apparatus with less stringent requirements for achieving uniformity on a 300 mm wafer. However, ALE has unique requirements due to the nature of its process steps, detailed herein.

An overview of ALE technology is presented by Karanik et al. in “Overview of atomic layer etching in the semiconductor industry” (J. Vac. Sci. Technol. A33, pages 020802 1-14, 2015), and further discussed in a book by Lill, “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. The material removal is quantified over multiple cycles and can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process.

The anisotropic ALE process or plasma enhanced ALE, which is the focus of the present invention, has been employed for etching various materials, demonstrating the technology's versatility:
Si and Ge as described in U.S. Pat. No. 10,727,073 to Tan et al.,
SiO2 as described in U.S. Pat. No. 9,620,382 to Oehrlein et al.,
C as described in U.S. Pat. Pub. Nos. 2017/0316935 and 2022/0216050 by Tan et al.,
W as described in U.S. Pat. Pub. No. 2020/0286743 from Lai et al and U.S. Pat. No. 10,096,487 to Yang et al,
Co as described in U.S. Pat. No. 10,096,487 to Yang et al,
Ru as described in U.S. Pat. Pub. No. 2022/0199422 by Yang et al.,
Other refractory metals and materials with high surface binding energy as described in U.S. Pat. No. 11,450,513 to Yang et al.,
Cu as described in WO Pat. Pub. No. 2022/046429 by Yang et al.,
GaN and other III-V materials as described in U.S. Pat. No. 10,056,264 to Yang et al.,
MRAM as described in U.S. Pat. No. 10,749,103 to Tan et al.,
EUV patterning as described in U.S. Pat. No. 9,922,839 to Wise et al., and
Surface smoothing of various materials as described in U.S. Pat. No. 10,304,659 to Karanik et al.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process—characterized by uniformity, smoothness, and selectivity. Karanik et al. in “Predicting synergy in atomic layer etching” (J. Vac. Sci. Technol. A35, pages 05C302 1-7, 2017) defined ALE synergy as:

$${ALE}_{synergy} S ( \% ) = \frac{EPC - ( α + β )}{EPC} \times 100 \% , \qquad [ 2 ]$$

EPC is “etch per cycle” representing the total thickness of material removed in one cycle, typically averaged over many cycles. The values of “α” and “β” are (undesirable) contributions from the surface modification step and the sputtering step, respectively. Ideally, synergy will approach 100% with no etching from either step alone. In practice, RIE in the surface modification step are nonzero because of presence of ions in the plasma which generates neutrals to modify the surface. In the sputtering step, physical sputtering of underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source, complicating the apparatus, it may increase the cost of the process.

Another solution to this problem, as disclosed in U.S. Pat. No. 10,014,192 to Singh, involves using a chamber divided into a plasma-generating region and a substrate-processing region by a separating plate structure. This plate blocks ions from reaching the substrate while utilizing low-energy metastable species to etch the substrate. However, by eliminating ions entirely from the process due to the restrictions imposed by the single plasma-generating region and the blocking mechanism, Singh's method cannot be used for high aspect ratio (HAR) structure formation. The lack of high-energy ions prevents effective etching of deep or narrow features, making this approach unsuitable for complex etching needs.

The present invention addresses this critical gap in ALE technology by introducing an improved chamber design that eliminates reactive ion etching (RIE) during the surface modification step by blocking ions completely. However, it allows for high-energy ions to be generated in a region near the substrate during the sputtering step, specifically to etch high aspect ratio structures. These high-energy ions are crucial for reaching the bottom of deep or narrow features, providing the necessary directional control for precise etching in HAR structures. This method enables a more controlled and accurate etching process, enhancing the quality and consistency of semiconductor devices.

### SUMMARY

The invention pertains to a process chamber design that improves the efficiency and control of ALE processes. The chamber is divided into an upper section functioning as an ICP chamber and a lower section functioning as a capacitively coupled plasma CCP chamber. A key component of the chamber is the GIF, which is placed between the upper and lower chambers. The GIF prevents ions from reaching the substrate during the surface modification step of the ALE process, ensuring a precise and ion-free modification stage.

In some embodiments, the GIF is made of conductive materials such as aluminum or silicon and is grounded through the chamber body or other structures within the chamber. Its primary function is to block ions while allowing neutrals to pass through its openings and interact with the substrate surface. This design provides a significant improvement over conventional ALE processes, where ion interaction with the substrate can cause unwanted effects such as RIE.

In various implementations, the design of the GIF is versatile, with its openings not confined to a specific shape. The openings can be circular, square, rectangular, elliptical, hexagonal, or octagonal, and their size and depth can be varied according to the process requirements. In some embodiments, the openings may be angled relative to the substrate's vertical direction to enhance ion blocking efficiency while allowing the passage of neutrals. This flexibility is crucial for optimizing the ion-blocking function while ensuring that chemically active neutrals can reach the substrate.

Dividing the process chamber into an upper ICP chamber and a lower CCP chamber offers several advantages. The upper ICP chamber efficiently generates neutrals for the surface modification step, while the lower CCP chamber specializes in producing energetic ions with the necessary directionality for the removal of modified layers during the sputtering step. This dual functionality is particularly advantageous for high aspect ratio structure formation, where high-energy ions are required to effectively etch deep or narrow features with precision. The controlled generation of ions in the CCP chamber allows for better directionality and energy control, ensuring that the etching process is highly accurate.

Furthermore, the chamber design allows for enhanced control over the ALE process. The surface modification step can be rapidly completed by increasing the RF power delivered to the plasma source in the upper chamber. In some embodiments, the bias unit can be tailored to generate ions with the tight energy distribution, a critical factor for the formation of high aspect ratio structures. By fine-tuning ion energy, the process ensures accurate etching without over-etching or damaging sensitive layers, particularly in deep trenches or narrow features.

In summary, the innovative chamber design significantly enhances the ALE process by addressing the limitations of conventional ALE methods. The design ensures a more efficient and controlled process, allowing for precise etching of high aspect ratio structures by utilizing high-energy ions in the lower chamber while preventing ion interaction during the surface modification step. This advancement in ALE technology provides new possibilities for achieving highly precise etching results in semiconductor manufacturing, leading to improved device performance and reliability.

### BRIEF DESCRIPTIONS OF DRAWINGS

To enhance clarity, the following description refers to the accompanying drawings:

FIG. 1A: Depicts an exemplary plasma processing chamber, which incorporates a GIF that partitions the chamber into an upper and a lower chamber.

FIG. 1B: Displays a top-view illustration of the GIF, highlighting its design.

FIG. 1C: Offers a detailed view of an exemplary design for the GIF.

FIG. 2: Illustrates alternative embodiments and designs of the GIF.

FIG. 3: Captures the functionalities of the upper and lower chambers during an ALE process, which includes a surface modification step and a sputtering step.

FIG. 4A: Highlights a first implementation for introducing gas into the lower chamber.

FIG. 4B: Highlights a second implementation for introducing gas into the lower chamber.

FIG. 4C: Highlights a third implementation for introducing gas into the lower chamber.

FIG. 4D: Highlights a fourth implementation for introducing gas into the lower chamber.

FIG. 5: Provides a step-by-step flowchart that describes the operation of an ALE process within the exemplary plasma process chamber.

### DETAILED DESCRIPTIONS

To ensure comprehensive understanding, this section delves into detailed embodiments of the present invention. Although specific examples are provided for clarity, modifications and variations that align with the subsequent claims are deemed appropriate. Conventional methods and components are discussed to underscore the distinct features of the invention.

### Terms Used in this Patent Application are Defined as Follows

Aspect Ratio: The ratio of the height to the width of a feature on a semiconductor wafer, crucial for defining the geometry and performance of microstructures.
Bias Unit: A component that generates a plasma and a bias voltage to accelerate ions toward the wafer held by an electrostatic chuck (ESC). This voltage creates an electric field that enhances ion bombardment, essential for controlling ion energy and directionality in processes like etching.
Chamber: An enclosed environment within semiconductor manufacturing equipment where processes such as etching, or deposition occur.
Chuck: A component in semiconductor manufacturing equipment that holds and secures the wafer during processing.
Electrostatic Chuck (ESC): A chuck that uses electrostatic forces to hold a substrate in place during semiconductor manufacturing processes, ensuring uniform clamping and stability.
Gas/precursor Distribution Unit: A component in a plasma process chamber designed to introduce and distribute process gases or precursors across a substrate. It can take various forms, such as an injector, positioned centrally or at specific angles, or a showerhead featuring a perforated plate to disperse gas across the substrate. Side injection mechanisms can introduce gas from the chamber's sides, promoting lateral flow.
Gas Source: The origin or supply point of process gases used in a vacuum process chamber, typically connected to a facility's centralized gas distribution system. A gas box regulates and controls the flow of gases, delivering them under controlled conditions to ensure proper gas composition and purity.
Grounded Ion Filter (GIF): A conductive plate positioned parallel to the substrate to divide the vacuum chamber into upper and lower chambers. The GIF has openings that allow neutrals to pass through and react with the substrate placed on a chuck, while blocking ions. During the sputtering step of an ALE process, the GIF serves as the grounded plate of a capacitor.
High Aspect Ratio: Refers to semiconductor wafer features with significantly greater height than width, often challenging to manufacture due to difficulties in achieving uniformity and precision.
Lower Chamber: The lower section of a vacuum chamber, operating as a CCP reactor during the sputtering step of an ALE process.
Plasma enhanced ALE (or simply ALE): An etching process used in semiconductor manufacturing that removes material layer by layer at the atomic scale, offering precise control over etch depth and profile. ALE operates in cycles, each consisting of a surface modification step and a sputtering step. In the surface modification step, the material is chemically altered to form a reactive layer, which is selectively removed during the sputtering step through physical ion bombardment, ensuring high precision and selectivity.
Plasma Process Chamber: A specialized vacuum chamber designed for processes involving plasma, a highly ionized gas. These chambers are used in semiconductor manufacturing for processes such as etching and deposition, where plasma provides the necessary energy to activate chemical reactions or remove material from the wafer surface.
Plasma Source: A device that generates plasma for semiconductor manufacturing processes like etching, deposition, and surface modification. Common types include inductively coupled plasma (ICP), transformer coupled plasma (TCP), and capacitively coupled plasma (CCP). ICP uses an RF magnetic field from a coil to produce plasma, TCP employs a planar coil and RF energy to create plasma through transformer action, and CCP generates plasma by applying RF power across two electrodes, creating an electric field that ionizes the gas.
Process System: The integrated equipment and machinery used in semiconductor manufacturing to carry out processes such as deposition, etching, and cleaning.
Reactive Ion Etching (RIE): A plasma-based etching technique in which both physical ion bombardment and chemical reactions work synergistically to remove material from a substrate. In RIE, reactive gas is ionized in plasma, creating a mix of ions and neutral species. Ions are accelerated toward the substrate by an electric field, physically sputtering the material, while chemically reactive neutrals enhance etching.
Resonator: A device or circuit component designed to resonate at a specific radio frequency, crucial for applications like RF impedance matching in RF circuits. Resonators can be constructed using various technologies, such as LC circuits (inductor-capacitor circuits), and provide high selectivity and stability at their resonant frequency.
RF Power Generator: A device that generates radio frequency power for energizing plasma in semiconductor manufacturing processes like etching or deposition.
Sheath: In plasma, the boundary layer between the plasma and a surface, where an electric field forms. This region controls the energy and flux of ions and electrons reaching the surface, influencing processes like etching and deposition.
Substrate: The base material, typically a silicon wafer, upon which semiconductor devices are fabricated.
System Controller: The central unit that manages and controls the various operations and parameters of plasma process systems, ensuring coordinated and efficient functioning.
Tailored Waveform Generator: A device that produces custom-designed electrical waveforms to optimize plasma processes. By adjusting waveform shape, frequency, and amplitude, it allows precise control over plasma characteristics, enhancing etching and deposition uniformity, performance, and selectivity.
Transmission Line (in RF): A specialized conductor or set of conductors designed to carry radio frequency (RF) signals with minimal loss and distortion. In semiconductor manufacturing, transmission lines efficiently transfer RF power from the generator to the plasma source, assisting proper impedance matching to minimize reflections and power losses for reliable RF energy delivery.
Upper Chamber: The upper section of a vacuum chamber separated by a GIF. It operates as an ICP reactor during the surface modification step of an ALE process.
Vacuum Chamber: An enclosed space from which air and other gases are removed to create a low-pressure environment. These chambers are used in semiconductor manufacturing processes such as deposition and etching to maintain controlled atmospheric conditions, prevent contamination, and ensure precision.
Window: In a vacuum chamber, this is a non-conductive, transparent or semi-transparent barrier separating the plasma generation region from external components, allowing electromagnetic waves, such as RF or microwave energy, to pass through.

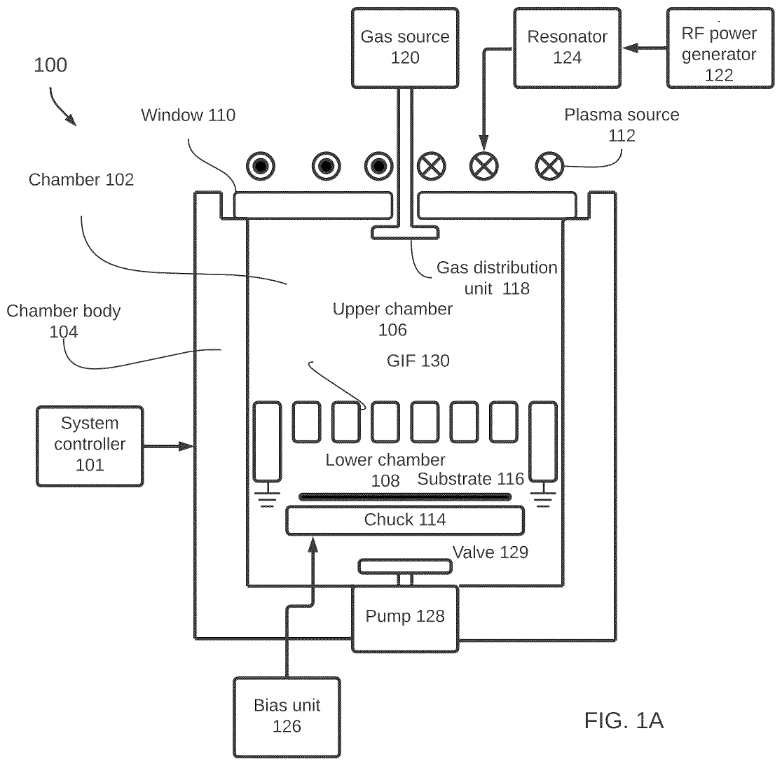

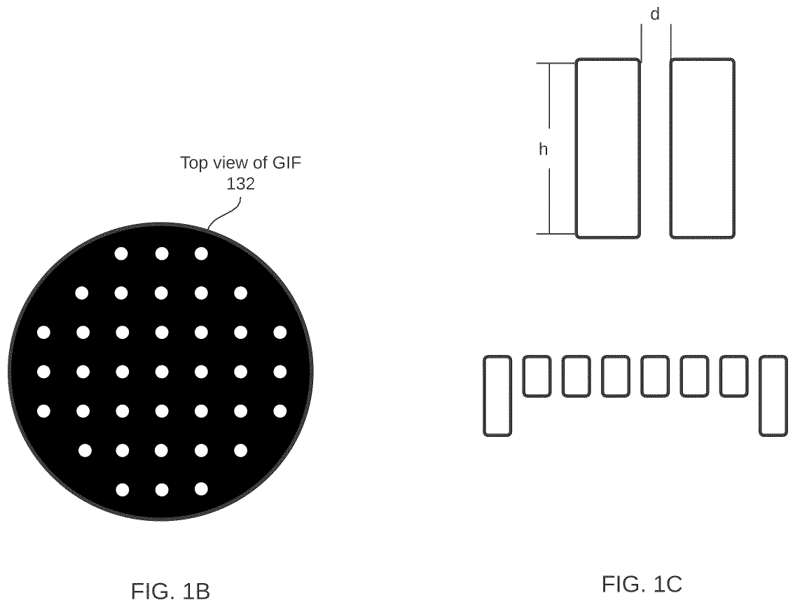

FIG. 1A illustrates an exemplary process system (100) incorporating a plasma process chamber (102). The operations within the chamber (102) are coordinated by a system controller (101). The process chamber (102) is enclosed by a chamber body (104), which creates a vacuum environment conducive to plasma processes. Atop the chamber body (104), a window (110), typically made from a dielectric material such as quartz or ceramic, seals the chamber (102).

Positioned above the window (110) is a plasma source (112), shown in FIG. 1A as consisting of a three-turn coil. However, the coil may have more or fewer than three turns depending on specific requirements, and it may also include multiple coils. Although a flat coil (112) is depicted in FIG. 1A, other configurations such as cylindrical or conical coils are permissible based on the specific implementation.

The plasma source (112) is connected to an RF power generator (122) through a resonator (124). The RF power generator (122) can produce RF power at single or multiple frequencies, including but not limited to 100 kHz, 400 kHz, 2 MHz, and 13.56 MHz. The resonator (124) is used to match the output impedance of the RF generator (122) to the plasma load within the chamber (102), accounting for the effects of transmission lines, as is well known in the art.

As depicted in FIG. 1A, a first gas distribution unit (118) connects to a gas source (120) through an opening in the window (110). Proper sealing of this opening is essential to maintain the vacuum environment within the chamber (102). The gas distribution unit (118) can take the form of an injector or a showerhead, depending on the specific implementation. In another variation, the window (110) may serve as a combined gas distribution unit and showerhead, sealing the vacuum chamber from above. Additionally, in some embodiments, the gas distribution unit (118) may include side-injection mechanisms for introducing gas into the chamber (102) from its sides. The system also includes a pump (128) and a valve (129) for evacuating unused gases and byproducts from the chamber (102).

Within the chamber (102), a chuck (114) is used to support a substrate (116). The chuck (114) may take various forms, including but not limited to, an electrostatic chuck (ESC) or a vacuum chuck.

The chamber (102) is further divided into an upper chamber (106) and a lower chamber (108) by a grounded ion filter (GIF) (130). The GIF (130) is positioned parallel to the substrate (116) and is made from conductive materials such as aluminum or silicon. The aluminum may be anodized to enhance erosion resistance. The GIF (130) can be grounded either through the chamber body (104) or via other grounded structures within the chamber (102), such as liners (not shown).

The upper chamber (106) functions as an ICP chamber. When plasma is ignited within the upper chamber (106), electrons, ions, and neutrals are generated. The GIF (130) acts as a barrier, blocking ions while allowing neutrals to pass through multiple openings in the GIF (130). FIG. 1B provides a top-view illustration of the GIF (130), highlighting an exemplary opening (132). In FIG. 1C, each hole has a diameter (d) and height (h). To effectively block ions, the diameter must be small, and the aspect ratio (h/d) must be substantial. The height of the openings may range from 0.1 mm to 10 mm, with aspect ratios spanning from 10 to 500.

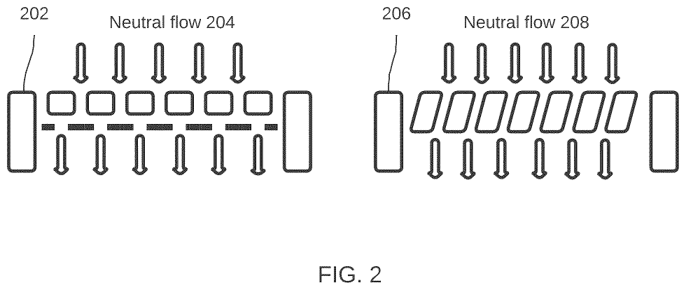

Several implementations of the GIF (130) are possible. FIG. 2 illustrates two examples. In the first example (202), the GIF (130) consists of a first group of vertical holes, a horizontal conducting channel connected to the holes in the first group, and a second group of vertical holes linked to the horizontal channel. The holes in the second group are intentionally misaligned with those in the first group, ensuring complete ion blocking while allowing neutral flow (204) through the GIF (130). In the second example (206), the openings in the GIF (130) are angled relative to the vertical direction of the GIF surface. This arrangement prevents ions from passing through the openings while allowing neutral flow (208) to diffuse through them.

These designs are merely illustrative, and numerous variations can be employed to achieve the functionalities of the GIF (130). The openings do not have to be circular; they can be of various shapes, including square, rectangular, elliptical, hexagonal, or octagonal. Additionally, the sizes and depths of the openings may vary, and their distribution may be either uniform or non-uniform. The GIF (130) may have varying thicknesses, and multiple methods of ion blocking can be utilized. For example, more than one horizontal conducting channel may be combined with angled openings. These variations are all within the scope of the present invention.

Returning to FIG. 1A, during operation, the upper chamber (106) functions as an ICP chamber. After plasma ignition, electrons diffuse toward the GIF (130) and the chamber body (104). Since the GIF (130) is grounded and lacks a blocking capacitor, the plasma sheath on its surface remains thin. This minimal sheath thickness can extend its operational lifetime and minimize ion bombardment on its surface.

The lower chamber (108) operates as a CCP chamber, with the GIF (130) acting as the grounded electrode and the chuck (114) functioning as the powered electrode. In one implementation, the chuck (114) receives RF power at a predetermined frequency from a bias unit (126) via a resonator (not shown). The frequency can range from 100 kHz to 100 MHz. In another implementation, the bias unit (126) additionally delivers RF power at multiple frequencies, including but not limited to 100 kHz, 400 kHz, 1 MHz, 2 MHz, 13.56 MHz, and 60 MHz. The bias unit (126) establishes a bias on the chuck (114) and can ignite plasma in the lower chamber (108) between the two electrodes. Typically, plasma density in a CCP reactor is lower than that in an ICP reactor but increasing the RF frequency from the bias unit (126) enhances the plasma density in the lower chamber (108). The bias unit (126) also increases the plasma sheath thickness to accelerate ions toward the substrate (116).

In another implementation, the bias unit (126) additionally includes a tailored waveform generator, which increases ion energy with tighter energy distributions for more precise ion bombardment.

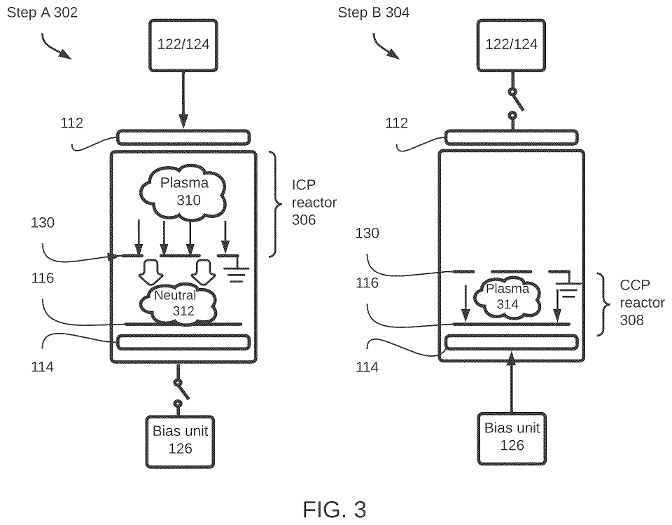

FIG. 3 illustrates functionalities of the upper and lower chambers during an ALE process, which includes a surface modification step A (302) followed by a sputtering step B (304). These steps are executed sequentially, and there may optionally be a gas purging step between transitions of the steps. Steps A (302) and B (304) together complete one cycle of the ALE process, which can be repeated multiple or many times to achieve the desired outcomes on the substrate (116). During the step A (302), the surface of the substrate is modified by chemically active neutrals (radicals). This modification results in the formation of one or a few monolayers on the surface, which exhibit weaker chemical bonds. In silicon ALE processes, chlorine is typically used to modify the silicon surface. Chlorine radicals form bonds with silicon, thereby weakening the neighboring silicon-silicon bonds. The modification step A (302) is self-limiting and reaches saturation once the surface has been exposed to the neutrals for a sufficiently long period. To maintain the ideal conditions for the ALE process, it is crucial to avoid ion bombardment during step A (302), as energetic ions can induce RIE, thereby detracting from an ideal ALE process.

During the sputtering step B (304), an inert gas such as argon is introduced to the chamber to generate an argon plasma. Positive argon ions are then accelerated by a sheath electrical field, which facilitates the removal of the modified surface layer. Once this layer is removed, the physical sputtering of the substrate's surface typically slows down. Like the modification step A (302), the sputtering step B (304) also exhibits self-limiting characteristics. In step B (304), it is important to avoid the chemically reactive gas used in the modification step to prevent RIE. However, in conventional ALE process chambers, completely avoiding RIE, particularly during the surface modification step, is challenging due to the self-bias induced by the plasma itself. In the present invention, as delineated in the chamber design in FIG. 1A, this issue is resolved by dividing the chamber (102) into an upper chamber (106) and a lower chamber (108).

As illustrated in FIG. 3, during the surface modification step A (302), the bias unit (126) ceases to supply the RF power to the chuck (114). In this configuration, the upper chamber (106) operates as an ICP reactor (306). Within this plasma (310), ions are prevented from passing through the GIF (130), while neutrals (312) can diffuse into the lower chamber (108). These neutrals (312) interact with the substrate (116), effectively modifying its surface.

During the sputtering step B (304), the plasma source (112) ceases to receive RF power from the RF power generator (122) via the resonator (124), resulting in no plasma generation in the upper chamber (106). In this step, the bias unit (126) supplies RF power to the substrate (116). The introduction of an inert gas, such as argon, into the lower chamber (108) then ignites a plasma (314), thereby activating a CCP reactor (308). The ions within the plasma (314) are then accelerated, thereby removing the modified layer formed during the step A (302).

In an alternative implementation, the bias unit (126) additionally produces a tailored waveform. This waveform can generate ions with a narrowly defined energy distribution, which is crucial for the formation of structures with high aspect ratios. In some implementations, this tailored waveform may be combined with a RF signal to achieve the desired results.

By preventing ions from reaching the substrate surface, the present inventive concept enhances the ideality of the ALE process while also potentially shortening the duration of step A, achieved by increasing the RF power delivered to the plasma source (112). Additionally, a CCP reactor (308) used in the sputtering step B (304) is more effective in generating energetic ions with improved directionality, which aids in removing modified layers from high aspect ratio structures.

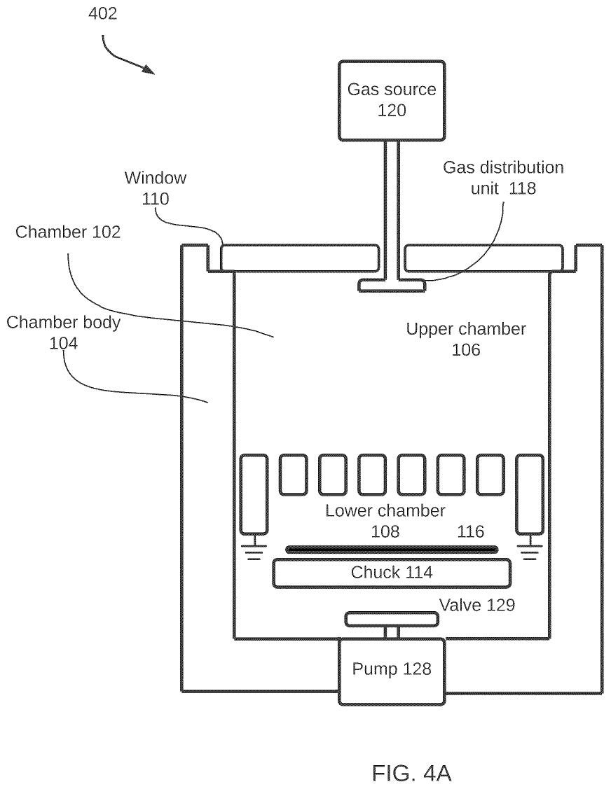

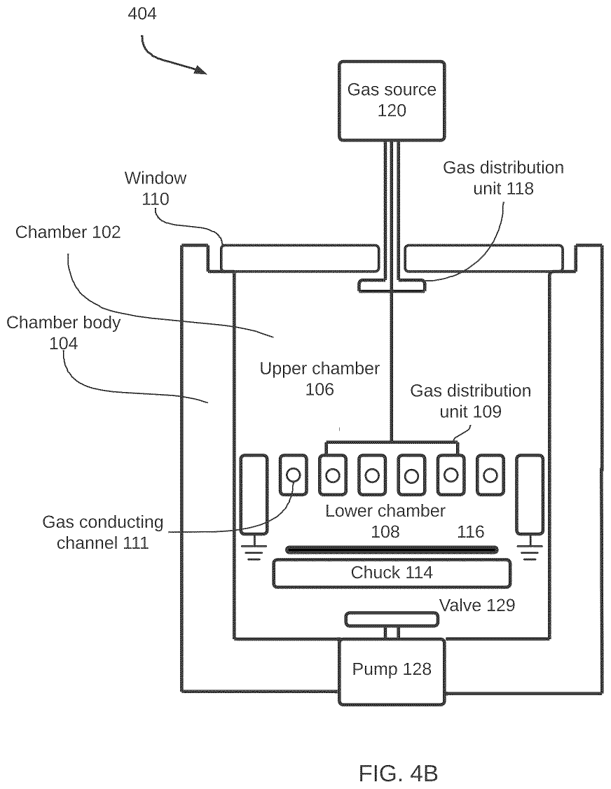

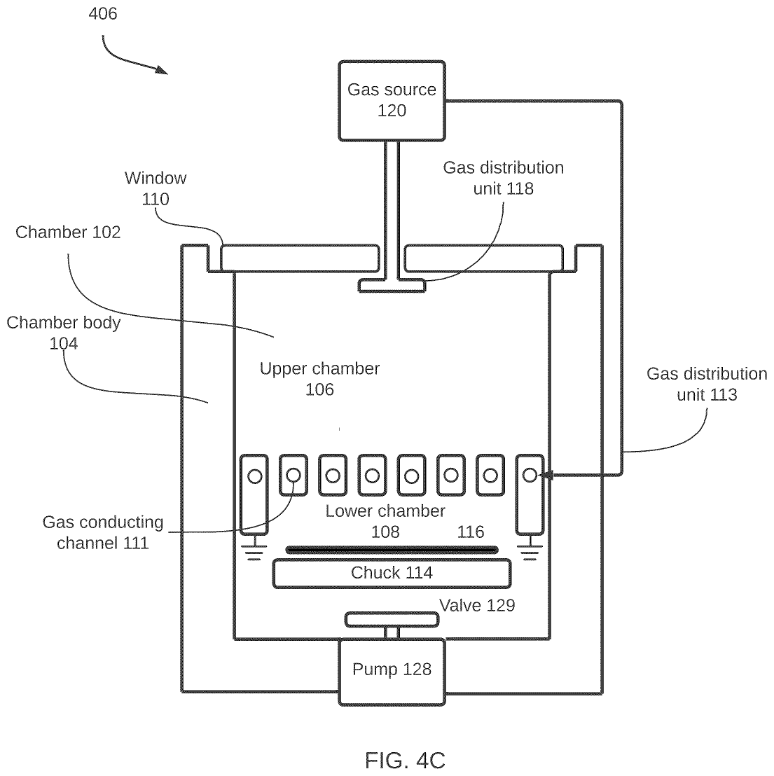

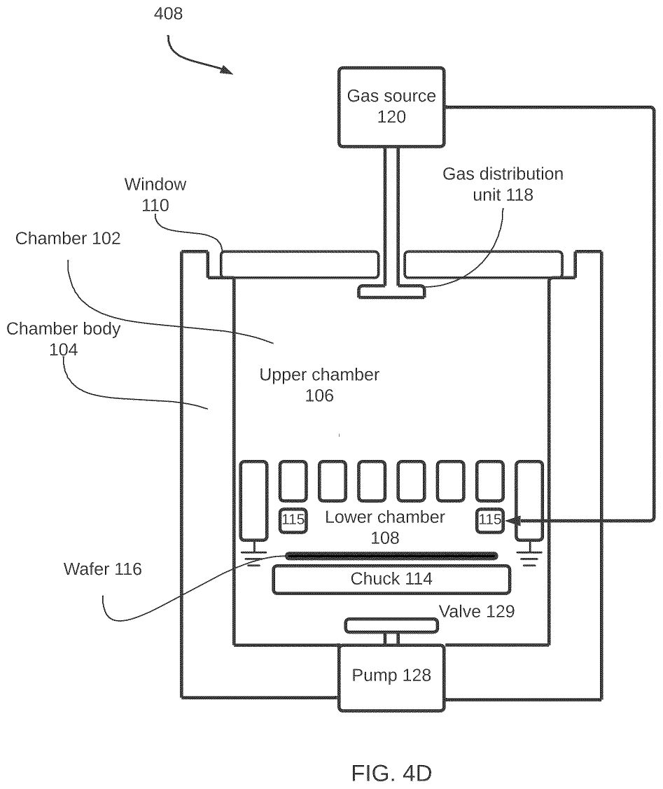

FIGS. 4A-D showcase four exemplary implementations for gas injection into the lower chamber (108) through either the first or a second gas distribution unit, using argon as an illustrative example without limiting the scope of the inventive concept. In the first implementation, shown as 402 in FIG. 4A, argon is drawn from the gas source (120) and distributed to the upper chamber (106) through the first gas distribution unit (118). The argon in the upper chamber (106) is then diffused into the lower chamber (108) through openings in the GIF (130). In the second implementation, shown as 404 in FIG. 4B, the GIF (130) also serves as a showerhead, incorporating the second gas distribution unit (109). This unit draws argon gas from the gas source (120) and directs it into the lower chamber (108) through its gas conducting channels (111). In the third implementation, shown as 406 in FIG. 4C, an internal gas distribution unit 113, one of the implementations of the second gas distribution unit, draws gas from the gas source (120) at the side of the GIF (130). This side may include multiple receiving ports arranged symmetrically. The gas is subsequently distributed to the lower chamber (108) through the gas conducting channel (111). In the fourth implementation, shown as 408 in FIG. 4D, a gas distribution unit 115, yet another version of the second gas distribution unit, is positioned below the GIF (130). Argon is received from the gas source (120) and injected directly into the lower chamber (108). The implementations depicted in FIGS. 4A-D are merely exemplary, and numerous variations and modifications are possible. All such variations and modifications are within the scope of the present inventive concept.

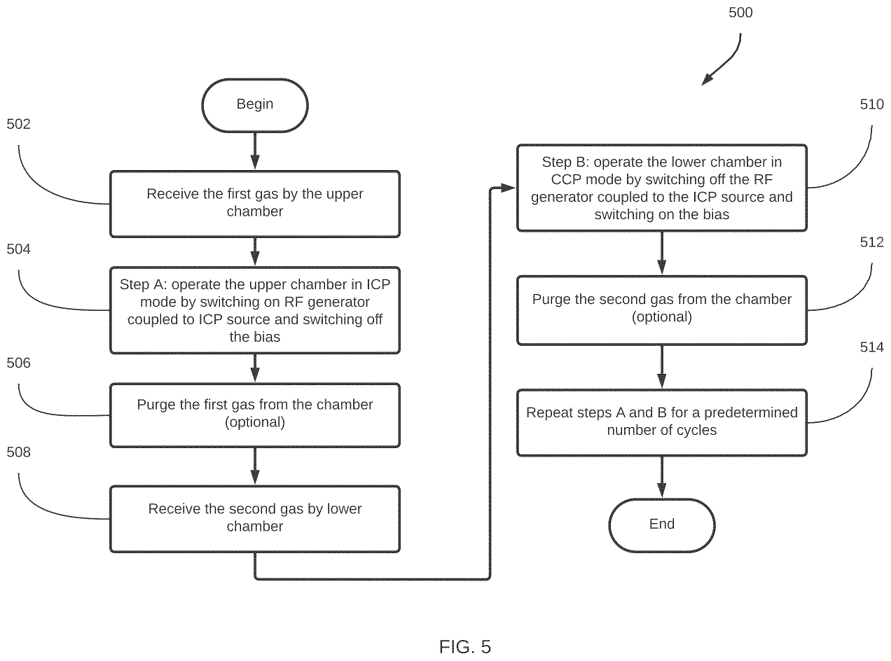

FIG. 5 outlines the flowchart of the ALE process 500 utilizing the exemplary process system 100. The process (500) starts with receiving a first gas by the gas distribution unit (118) and delivering it into the up chamber 106 (502). Following this, the system controller 101 operates the chamber (102) in the surface modification step A of the ALE process (504). During this step, the plasma source (112) receives RF power from the RF power generator (122) through the resonator (124), while the bias unit (126) ceases to provide the RF power to the chuck (114). This results in a plasma being ignited in the up chamber (106). However, the ions are blocked by the GIF (130), allowing only neutrals, including radicals, to diffuse through the openings in the GIF (130) into the lower chamber (108), where they modify the surface of the substrate (116).

After this surface modification step, the first gas and related neutrals may be optionally purged from both the up chamber (106) and lower chamber (108) (506). A second gas, like argon, is then received by the lower chamber (108) through various possible implementations as shown in FIGS. 4A-D (508). Following this, the system controller (101) operates the chamber (102) in the sputtering step of the ALE process (510). During this step, the plasma source (112) stops receiving RF power from the RF power generator (122), and the bias unit (126) provides RF power in one or multiple frequencies to the chuck (114). This results in a plasma being ignited in the lower chamber (108), behaving like a CCP reactor. The RF power from the bias unit (126) also establishes a bias to the substrate (116), which increases the thickness of the plasma sheath on the surface of the substrate (116). This, in turn, accelerates the ions towards the surface to remove the modified layer. After the completion of the sputtering step, the chamber (102) may be optionally purged to remove the second gas (512). Finally, the ALE cycle comprising the steps A and B is repeated according to a process recipe to complete the ALE process (514).

1. A plasma process chamber configured for ALE, the chamber comprising:
an upper chamber and a lower chamber separated by a GIF, wherein the upper chamber includes an ICP source or a TCP source, and the lower chamber includes a chuck operatively coupled to a bias unit; and
a system controller configured to execute an ALE process comprising a surface modification step and a sputtering step in sequence as a single ALE cycle,
wherein, during the surface modification step, the chamber operated by the system controller is configured to:
initiate a plasma comprising electrons, ions and neutrals in the upper chamber by supplying RF power from a coupled RF power generator to the ICP source or the TCP source,
prevent the ions from entering the lower chamber by the GIF, and
permit neutrals to pass through openings in the GIF to modify a surface of a substrate held by the chuck without applying a bias to the chuck,
wherein, during the sputtering step, the chamber operated by the system controller is configured to:
generate an inert gas plasma comprising electrons, ions and neutrals in the lower chamber by operating the lower chamber as a CCP reactor, using the chuck and the GIF as two electrodes, and
supply RF power from the bias unit to the chuck, while ceasing the supply of RF power from the RF generator to the ICP source or the TCP source.

2. The chamber of claim 1, wherein the openings in the GIF are dimensioned and configured such that the leakage of ions through the openings is negligible.

3. The chamber of claim 1, wherein the openings in the GIF are oriented at an angle relative to the vertical direction with reference to the substrate surface.

4. The chamber of claim 1, wherein the openings in the GIF comprise a first group of openings, a horizontal conducting channel connected to the first group of the openings and a second group of openings connected to the horizontal conducting channels, wherein the openings in the second group are misaligned from the openings in the first group.

5. The chamber of claim 1, wherein during the surface modification step, a first gas is conveyed from a gas source to the upper chamber through a first gas distribution unit positioned within the upper chamber.

6. The chamber of claim 5, wherein during the sputtering step, a second gas is transported from the gas source to the upper chamber via the first gas distribution unit in the upper chamber and subsequently diffuses into the lower chamber through the openings in the GIF.

7. The chamber of claim 5, wherein a second gas is transported from the gas source to the lower chamber through a second gas distribution unit integrated with the GIF.

8. The chamber of claim 5, wherein the second gas is transported from the gas source to the lower chamber through a second gas distribution unit placed in the lower chamber.

9. The chamber of claim 1, wherein the bias unit is configured to supply RF power at one or more frequencies.

10. The chamber of claim 9, wherein the bias unit further includes a tailored waveform generator.

11. A method for performing an ALE process on a substrate, the method comprising:
placing the substrate on a chuck situated within a plasma process chamber, the chamber being divided into an upper chamber and a lower chamber by a GIF;
conducting a surface modification step for modifying the surface of the substrate, the surface modification step comprising:
a. introducing a first process gas from a gas source to the upper chamber via a first gas distribution unit;
b. igniting a plasma comprising electrons, ions, and neutrals within the upper chamber by applying RF power to an ICP or a TCP source positioned atop the upper chamber;
c. exposing the substrate to neutrals diffused from the upper chamber to the lower chamber through a plurality of openings in the GIF, with the ions being obstructed by the GIF, for a predetermined duration;
conducting a sputtering step, the sputtering step comprising:
a. introducing a second process gas from a gas source to the lower chamber via either a first gas distribution unit from the upper chamber or a second gas distribution unit from the gas source directly;
b. igniting a plasma comprising electrons, ions, and neutrals within the lower chamber by applying RF power to the chuck via a bias unit;
c. exposing the substrate to the plasma for a predetermined duration to remove the modified surface of the substrate; and
repeating the modification step and the sputtering step for a specified number of cycles.

12. The method of claim 11, wherein the process additionally comprises a step of purging both the upper and lower chambers during transitions between the surface modification and the sputtering steps, or between the sputtering and the surface modification steps.

13. The method of claim 11, wherein the first process gas comprises a halogen-containing gas.

14. The method of claim 11, wherein the second process gas comprises an inert gas.

15. The method of claim 11, wherein the RF power applied to the chuck from the bias unit comprises RF powers at multiple frequencies.

16. The method of claim 15, wherein the bias unit further comprises a tailored waveform generator.

17. A process system, comprising:
a plasma process chamber defined by a chamber body;
a GIF dividing the chamber into an upper chamber and a lower chamber, wherein the upper chamber is further defined by a window and the GIF, and the lower chamber is further defined by the GIF and a chuck, with the GIF being a conductive material featuring a plurality of openings that allow neutrals to migrate from the upper chamber to the lower chamber while obstructing ions from entering the lower chamber from the upper chamber;
an ICP source connected to a first RF power generator to produce a first plasma in the upper chamber, functioning as an ICP reactor; and
a second RF power generator linked to the chuck to create a second plasma in the lower chamber, operating as a CCP reactor.

18. The chamber of claim 17, wherein the GIF is grounded through a liner of the chamber body.

19. The chamber of claim 17, wherein the conductive materials for the GIF further include silicon or aluminum.

20. The chamber of claim 17, wherein the openings in the GIF are dimensioned and configured such that the leakage of ions through the openings is negligible.
